(19) United States
(12) Patent Application Publication
(10) Pub. No.: US 2007/0018277 A1
(43) Pub. Date: Jan. 25, 2007

(54) Field effect transistor and semiconductor device

(75) Inventor: Hideaki Matsuhashi, Tokyo (JP)

Correspondence Address: NIXON PEABODY, LLP, 401 9TH STREET, NW, SUITE 900, WASHINGTON, DC, 20004-2128, US

(73) Assignee: Oki Electric Industry Co., Ltd., Tokyo (JP)

(21) Appl. No.: 11/474,395

(22) Filed: Jun. 26, 2006

(30) Foreign Application Priority Data
Jul. 5, 2005 (JP) 2005-195885

(51) Int. Cl. H01L 29/00

(52) U.S. Cl. 257/507

(57) ABSTRACT

Channel forming sections that are respectively p types and have hexahedral structures are provided in a silicon epitaxial layer of an SOS substrate. Gate oxide films and a gate electrode are provided at both side surfaces of the channel forming sections. Thus, channels can be formed along both side surfaces of the channel forming sections. In the SOS substrate, compressive stress lying in the direction parallel to the surface of the silicon epitaxial layer is produced in the silicon epitaxial layer upon its manufacture. Therefore, when the channels are formed along the upper surfaces of the channel forming sections, the mobility of electrons is reduced. On the other hand, since tensile stress occurs in the direction normal to the surface of the silicon epitaxial layer, the mobility of electrons can be made high by forming channels along the side surfaces of the channel forming sections, so that the mobility of electrons can be set high and an on-current can be increased.

### BACKGROUND OF THE INVENTION

The present invention relates to a field effect transistor (FET) fabricated using an SOS (Silicon on Sapphire) substrate, and a semiconductor device using the field effect transistor.

There has heretofore been known a semiconductor substrate in which a silicon semiconductor layer is formed on an insulated board. This is referred to as an SOI (Silicon on Insulator) substrate. The SOI substrate is suitable for the fabrication of an integrated circuit very high in integration degree. As a technique for fabricating an MOS (Metal Oxide Semiconductor) type field effect transistor (hereinafter described as MOSFET) on the SOI substrate, there has been known one described in, for example, a patent document 1 (Japanese Unexamined Patent Publication No. Hei 1(1989)-183855).

There has also been known an SOI substrate in which a silicon epitaxial layer is formed on a sapphire substrate. This is called an SOS substrate. As a technique for fabricating a MOSFET on the SOS substrate, there has been known one described in, for example, a patent document 2 (Japanese Patent Application Publication No. Hei 8(1996)-512432). Since sapphire is very high in insulating property, the MOSFET formed on the SOS substrate becomes very small in parasitic capacitance. Hence the MOSFET is excellent in high frequency performance. Since the insulating property of the sapphire is high, an inductor very high in Q value (Q=ωL/R; where ω: angular frequency, L: inductance, R: effective resistance value) can be formed in the SOS substrate. On the other hand, an integrated circuit chip can be manufactured at the same degree as the cost of a silicon chip having a bulk structure or at a cost cheaper than it even though the expensive sapphire substrate is used, due to the reasons that, for example, when the SOS substrate is used, a CMOS (Complementary Metal Oxide Semiconductor) process identical to the case in which a normal silicon substrate is used, can be utilized and a well forming process is unnecessary. Due to such reasons, the integrated circuit using the SOS substrate is expected to be applied to a high-frequency circuit at a Gigahertz level as an alternative to a GaAs integrated circuit expensive in both substrate and manufacturing cost.

However, a drawback arises in that when the MOSFET is fabricated on the SOS substrate, an on-current of an n channel FET becomes very small as compared with the case in which the normal silicon substrate is used. It is considered that this results from the following causes.

A deposition temperature at which the silicon epitaxial layer is formed on the sapphire substrate, is a very high temperature (e.g., about 900° C. to 1000° C.). Therefore, when a substrate temperature is reduced to room temperature after deposition, the sapphire substrate and the silicon epitaxial layer shrink. There is, however, a nearly-double difference in thermal expansion coefficient between the sapphire substrate and the silicon epitaxial layer. Accordingly, there is a large difference even in the degree of shrinkage therebetween at a reduction in temperature. Therefore, compressive stress is produced in the silicon epitaxial layer when it is cooled to room temperature. Due to such compressive stress, a crystal lattice interval of the silicon epitaxial layer shrinks in the direction parallel to the surface of the substrate. While the mobility of holes becomes large as the lattice interval becomes small, the mobility of electrons is reduced. Therefore, when the MOSFET using the SOS substrate is adopted, an on-current of a p channel FET becomes large as compared with the MOSFET using the normal silicon substrate, whereas an on-current of an n channel FET becomes small.

As a method for resolving such drawbacks, it is considered that one described in, for example, a patent document 3 (Japanese Unexamined Patent Publication No. 2003-060076) is applied. In the patent document 3, a film having tensile stress is formed on an FET element forming surface to relax shrinkage of each channel region (refer to, for example, the paragraph 0043 of the patent document 3). Even though, however, such a technique is applied to an SOS substrate technique, an on-current of an n channel FET cannot be increased sufficiently.

### SUMMARY OF THE INVENTION

An object of the present invention is to provide a technique for forming a field effect transistor sufficiently large in on-current on an SOS substrate.

According to a first aspect of the present invention, there is provided a field effect transistor formed in a semiconductor substrate having a sapphire substrate and a silicon semiconductor layer.

The field effect transistor comprises channel forming sections each being a p type and having a hexahedral structure, which are formed using the silicon semiconductor layer, an n type source region and an n type drain region both formed using the silicon semiconductor layer so as to contact their corresponding end surfaces of the channel forming sections, and a gate electrode formed so as to contact side surfaces of the channel forming sections through gate insulating films.

According to a second aspect of the present invention, there is provided a semiconductor device formed in a semiconductor substrate having a sapphire substrate and a silicon semiconductor layer.

The semiconductor device comprises an n type field effect transistor including first channel forming sections each being a p type and having a hexahedral structure, which are formed using the silicon semiconductor layer, an n type source region and an n type drain region both formed using the silicon semiconductor layer so as to contact their corresponding end surfaces of the first channel forming sections, and a first gate electrode brought into contact with side surfaces of the first channel forming sections through first gate insulating films; and a p type field effect transistor including n type second channel forming sections each formed using the silicon semiconductor layer, a p type source region and a p type drain region both formed using the silicon semiconductor layer so as to contact their corresponding end surfaces of the second channel forming sections, and a second gate electrode brought into contact with upper surfaces of the second channel forming sections through second gate insulating films.

According to the first aspect of the present invention, since channels are formed at the side surfaces of the p-type channel forming sections, an n channel field effect transistor sufficiently large in on-current can be provided.

According to the second aspect of the present invention, since channels are formed at the side surfaces of the p-type channel forming sections and channels are formed at the upper surfaces of the n-type channel forming sections, a semiconductor device can be provided wherein both an n channel field effect transistor and a p channel field effect transistor are sufficiently large in on-current.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a conceptual view showing a structure of an n channel field effect transistor according to a first embodiment;

FIG. 2 is a conceptual view for describing a configuration of the n channel field effect transistor according to the first embodiment;

FIG. 3 is a conceptual view illustrating a structure of an n channel field effect transistor according to a second embodiment;

FIG. 4 is a conceptual view showing a structure of a semiconductor device according to a third embodiment;

FIG. 5 is a conceptual view illustrating the structure of the semiconductor device according to the third embodiment;

FIG. 6 is a conceptual view depicting the structure of the semiconductor device according to the third embodiment;

FIG. 7 is a conceptual view showing a structure of a semiconductor device according to a fourth embodiment;

FIG. 8 is a conceptual view illustrating the structure of the semiconductor device according to the fourth embodiment; and

FIG. 9 is a conceptual view depicting the structure of the semiconductor device according to the fourth embodiment.

### DETAILED DESCRIPTION OF THE PREFERRED EMBODIMENTS

Preferred embodiments of the present invention will hereinafter be described with reference to the accompanying drawings. Incidentally, the size, shape and physical relationship of each constituent element or component in the figures are merely approximate illustrations to enable an understanding of the present invention. Further, the numerical conditions to be explained below are nothing more than mere illustrated examples.

### First Preferred Embodiment

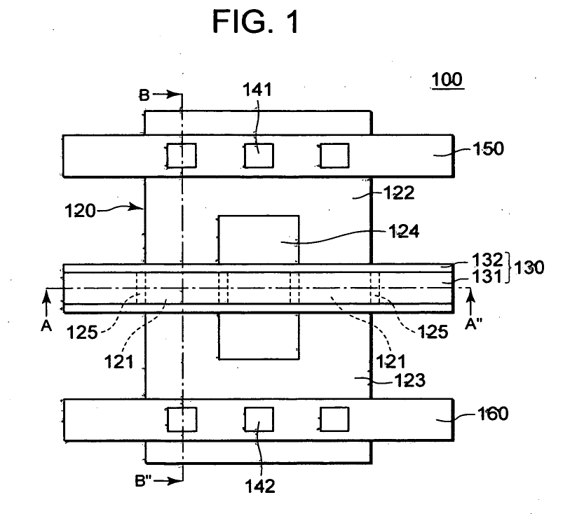

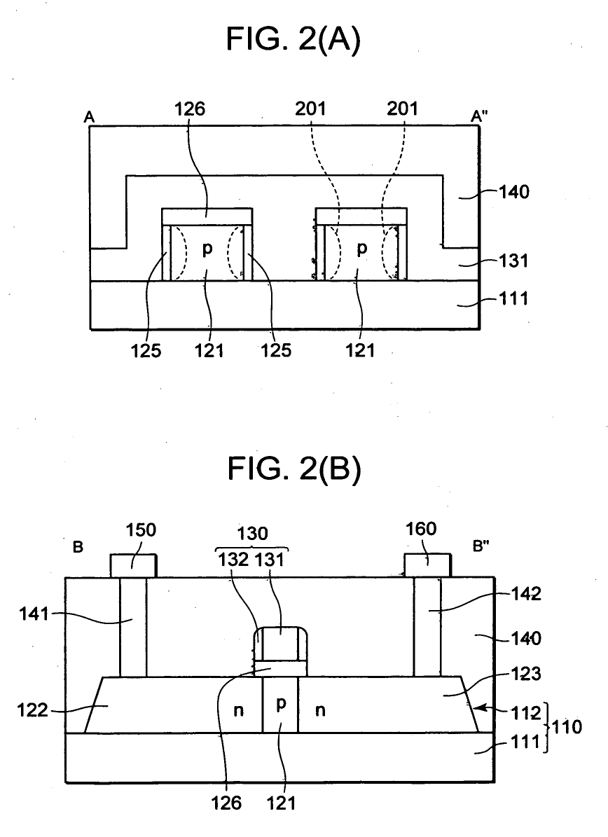

An n channel MOSFET according to a first embodiment of the present invention will be described below using FIGS. 1 and 2.

FIG. 1 is a plan view showing a structure of the n channel MOSFET according to the present embodiment, FIG. 2(A) is a sectional view taken along line A-A″ of FIG. 1, and FIG. 2(B) is a sectional view taken along line B-B″ of FIG. 2(B), respectively.

As shown in FIGS. 1 and 2, the n channel MOSFET 100 according to the present embodiment is obtained by forming a device or element forming area 120, a gate pattern 130, an intermediate insulating film 140 and wiring patterns 150 and 160 in an SOS substrate 110.

The SOS substrate 110 is constituted of a sapphire substrate 111 and a silicon epitaxial layer 112.

The element forming area 120 is formed in the form of a “□-shape, i.e., squared doughnut-shape” by etching processing of the silicon epitaxial layer 112. The element forming area 120 has two channel forming sections 121, a source region 122 and a drain region 123.

The channel forming sections 121 are disposed at a “□-shaped, i.e., squared doughnut-shaped” portion placed directly below the gate pattern 130 with an element or device isolation region 124 interposed therebetween. These channel forming sections 121 are shaped in the form of a hexahedral structure and are of p types. Gate oxide films 125 are respectively formed on both side surfaces of the channel forming sections 121. An oxide film 126 is formed on each of the upper surfaces of the channel forming sections 121. The oxide film 126 is formed in such a thickness that a gate electrode 131 (to be described later) does not form channels at the upper sides of the channel forming sections 121.

The source region 122 and the drain region 123 are formed so as to contact their corresponding end surfaces of the two channel forming sections 121. Each of the source region 122 and the drain region 123 is of an n type.

The gate pattern 130 has the gate electrode 131 and sidewalls 132. The gate electrode 131 is brought into contact with side surfaces of the two channel forming sections 121 through the gate oxide films 125 respectively. The sidewalls 132 are formed of an insulating material and are films for preventing the occurrence of a gap in the boundary between the gate electrode 131 and the intermediate insulating film 140.

The intermediate insulating film 140 is formed so as to cover the entire surfaces of the element forming area 120 and the gate pattern 130. The intermediate insulating film 140 includes one or plural contact holes 141 formed on the source region 122 and one or plural contact holes 142 formed on the drain region 123.

The wiring patterns 150 and 160 are formed on the intermediate insulating film 140. The wiring pattern 150 is connected to the source region 122 via the contact holes 141. Similarly, the wiring pattern 160 is connected to the drain region 123 via the contact holes 142.

The operation of the n channel MOSFET according to the present embodiment will next be explained.

When a potential is applied to the gate electrode 131, the potential is applied to the side surfaces of the respective channel forming sections 121 through the gate oxide films 125. Thus, channels 201 are formed at the respective side surfaces of the channel forming sections 121 (refer to FIG. 2(A)). Consequently, the source region 122 and the drain region 123 are brought into conduction so that a current flows.

As described above, the silicon epitaxial layer 112 of the SOS substrate 110 is reduced in crystal lattice interval as viewed in the direction parallel to the surface of the sapphire substrate 111 due to compressive stress. Since the channel forming sections 121 are also formed of the silicon epitaxial layer 112, they are reduced in crystal lattice interval as viewed in the corresponding direction. When the lattice interval as viewed in the direction parallel to the surface of the sapphire substrate 111 is now reduced, a lattice interval as viewed in the direction vertical to the surface of the sapphire substrate 111 increases to relax the compressive stress. That is, when compressive stress is produced in the direction parallel to the surface of the sapphire substrate 111, tensile stress is produced in the direction normal to the surface. Therefore, when the channels 201 are formed at the side surfaces of each channel forming section 121, the mobility of electrons increases rather than where no compressive stress occurs. Thus, the n channel MOSFET 100 according to the present embodiment increases in on-current as compared with the n channel MOSFET using the normal silicon substrate.

According to the discussions of the present inventors, when compressive stress occurs in the SOS substrate 110, the mobility of electrons is reduced 30% or so as compared with the case in which the compressive stress is not produced. On the other hand, when the channel is formed at the surface in which tensile stress occurs, the mobility of electrons can be increased by 30% or so as compared with the SOS substrate 110 free of the occurrence of compressive/tensile stress. Thus, according to the present embodiment, the mobility of electrons can be increased by 60% or so as compared with the conventional MOSFET (MOSFET in which the gate electrode is formed on the upper surface of the silicon epitaxial layer of the SOS substrate with the compressive stress produced therein).

On the other hand, when compressive stress occurs in the SOS substrate 110 in a p channel MOSFET, the mobility of holes is increased by 30% or so as compared with the case in which the compressive stress is not produced. Accordingly, a sufficient on-current can be obtained by a configuration similar to the conventional MOSFET.

Incidentally, although the channels 201 are formed at both side surfaces of the channel forming sections 121 in the present embodiment, the channel 201 may be formed at one side surface of each channel forming section 121. In this case, the areas at which the gate electrode 131 and the channel forming sections 121 are opposite to one another can be reduced, thus making it possible to reduce a parasitic capacitance.

### Second Preferred Embodiment

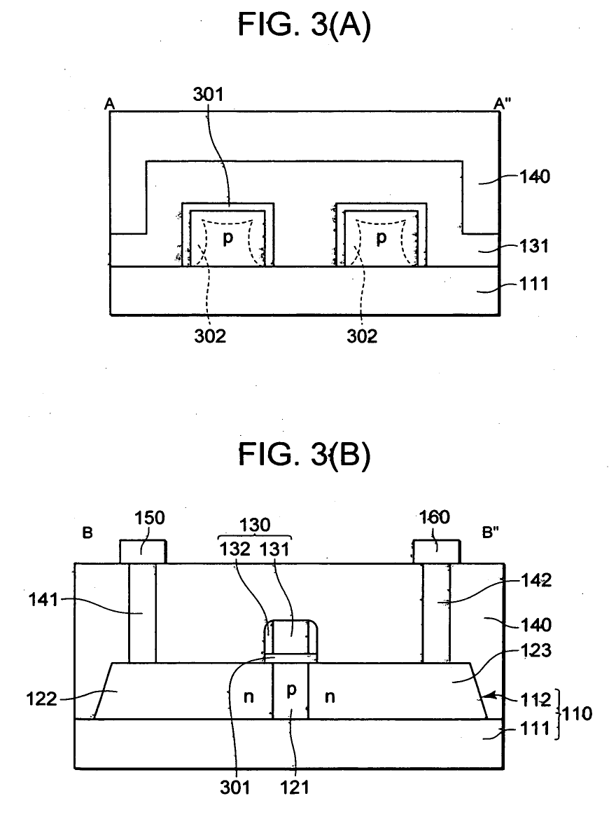

An n channel MOSFET according to a second embodiment of the present invention will next be described using FIG. 3.

A planar structure of the n channel MOSFET according to the present embodiment is similar to the first embodiment (refer to FIG. 1).

FIG. 3 is a conceptual view showing the structure of the n channel MOSFET according to the present embodiment, wherein FIG. 3(A) is equivalent to a cross-sectional view taken along line A-A″ of FIG. 1, and FIG. 3(B) is equivalent to a cross-sectional view taken along line B-B″ of FIG. 1, respectively. In FIG. 3, the same reference numerals as those shown in FIGS. 1 and 2 respectively indicate the same constituent elements as those shown in these figures.

As shown in FIG. 3, the n channel MOSFET according to the present embodiment is different from the MOSFET 100 according to the first embodiment in that an upper surface of each channel forming section 121 is also brought into contact with a gate electrode 131 through a gate oxide film 301. Thus, channels 302 are formed at both upper and side surfaces of the channel forming sections 121.

When the channel is formed at the upper surface of each channel forming section 121 as described above, the mobility of electrons corresponding to 70% or so is obtained as compared with the channel formed at the side surface of the corresponding channel forming section 121. Thus, the formation of the channels even at the upper surfaces of the channel forming sections 121 in addition to the formation thereof at the side surfaces of the channel forming sections 121 makes it possible to further increase an on-current of the n channel MOSFET. This effect is effective as the area of the upper surface of each channel forming section 121 increases.

Incidentally, although the n channel MOSFET has been explained here by way of example, the structure according to the present embodiment can be applied even to a p channel MOSFET. That is, such a gate electrode as to contact both side and upper surfaces of the channel forming sections is provided in the p channel MOSFET. Thus, since the channels can be formed at both surfaces large and small in hole mobility, the on-current can be increased than conventional.

### Third Preferred Embodiment

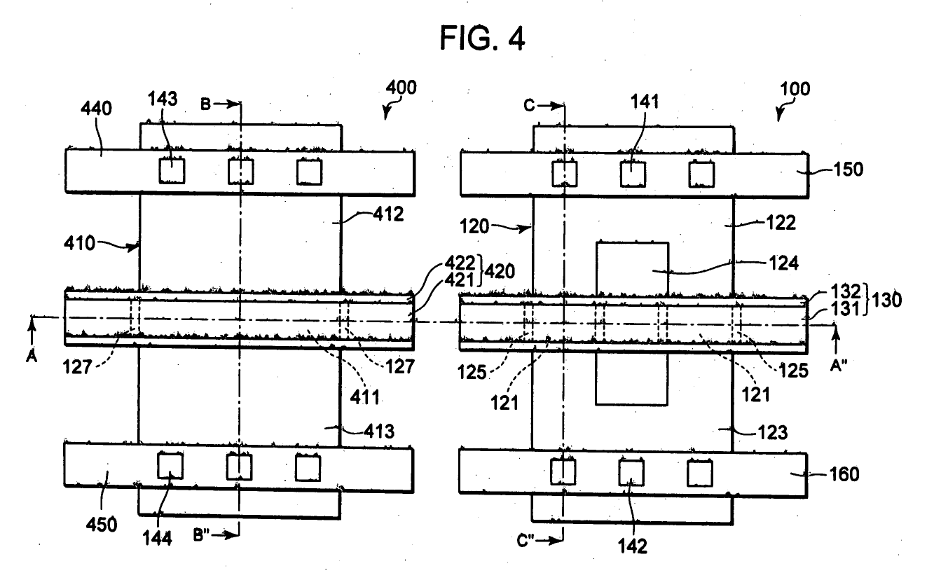

A semiconductor device according to a third embodiment of the present invention will next be explained using FIGS. 4 through 6.

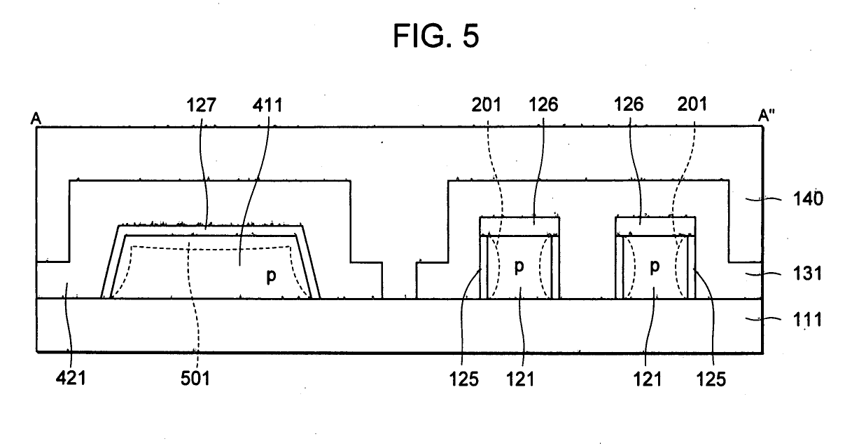

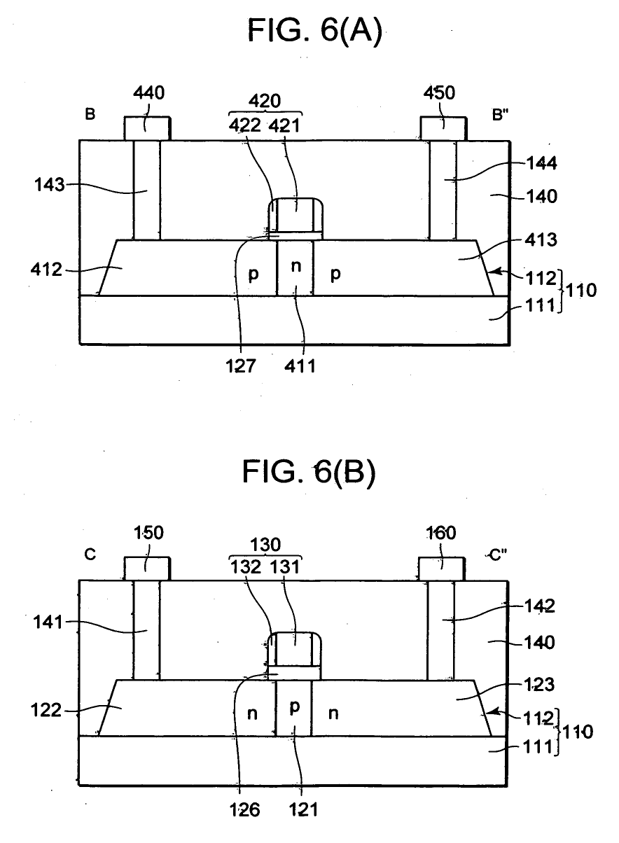

FIGS. 4 through 6 are conceptual views showing a structure of the semiconductor device according to the present embodiment, wherein FIG. 4 is a plan view thereof, FIG. 5 is a sectional view taken along line A-A″ of FIG. 4, FIG. 6(A) is a sectional view taken along B-B″ of FIG. 4, and FIG. 6(B) is a sectional view taken along C-C″ of FIG. 4, respectively. In FIGS. 4 through 6, the same reference numerals as those in FIGS. 1 and 2 respectively indicate the same constituent elements as those shown in these figures.

As shown in FIGS. 4 through 6, the semiconductor device according to the present embodiment is equipped with a p channel MOSFET 400 and an n channel MOSFET 100. The structure of the n channel MOSFET 100 is identical to that of the n channel MOSFET 100 according to the first embodiment. On the other hand, the p channel MOSFET 400 has a device or element forming area 410, a gate pattern 420, and wiring patterns 440 and 450.

The element forming area 410 is shaped in rectangular form by effecting etching processing on a silicon epitaxial layer 112. The element forming area 410 has a channel forming section 411, a source region 412 and a drain region 413.

The channel forming section 411 is disposed at a portion directly below the gate pattern 420. The channel forming section 411 is of an n type. A gate oxide film 127 is formed on the upper and side surfaces of the channel forming section 411.

The source region 412 and the drain region 413 are formed so as to contact their corresponding end surfaces of the channel forming section 411. Each of the source region 412 and the drain region 413 is of a p type.

The gate pattern 420 has a gate electrode 421 and sidewalls 422. The gate electrode 421 is brought into contact with the channel forming section 411 through the gate oxide film 127. The sidewalls 422 are formed of an insulating material and are films for preventing the occurrence of a gap in the boundary between the gate electrode 421 and an intermediate insulating film 140.

Contact holes 143 and 144 are defined in the intermediate insulating film 140 one by one or by plural by plural. The contact holes 143 are formed on the source region 412. The contact holes 144 are formed on the drain region 413.

The wiring patterns 440 and 450 are formed on the intermediate insulating film 140. The wiring pattern 440 is connected to the source region 412 through the contact holes 143. Similarly, the wiring pattern 450 is connected to the drain region 413 through the contact holes 144.

The operation of the semiconductor device according to the present embodiment will next be explained.

When a potential is applied to the gate electrodes 131 and 421, the potential is applied to the side surfaces of each channel forming section 121 and the upper and side surfaces of the channel forming section 411 through the gate oxide films 126 and 127. Thus, channels 201 are formed at their corresponding side surfaces of each channel forming section 121, and a channel 501 is formed at the upper surface of the channel forming section 411 (refer to FIG. 5). Thus, the source region 122 and the drain region 123 are brought into conduction so that a current flows, and the source region 412 and the drain region 413 are brought into conduction so that a current flows.

Since the channels 201 and 201 are formed at the side surfaces (i.e., surfaces at which tensile stress is being produced) of each channel forming section 121 in the n channel MOSFET 100 in a manner similar to the first embodiment, the mobility of electrons increases. Hence an on-current increases as compared with the n channel MOSFET using the normal silicon substrate. Since the channel 501 is formed at both of the upper surface (i.e., surface at which compressive stress is being produced) and side surfaces of the channel forming section 411 in the p channel MOSFET 400, the mobility of holes increases. Hence an on-current increases as compared with the p channel MOSFET using the normal silicon substrate. Thus, according to the semiconductor device according to the present embodiment, both the n channel MOSFET 100 and the p channel MOSFET 400 are capable of increasing the on-current.

### Fourth Preferred Embodiment

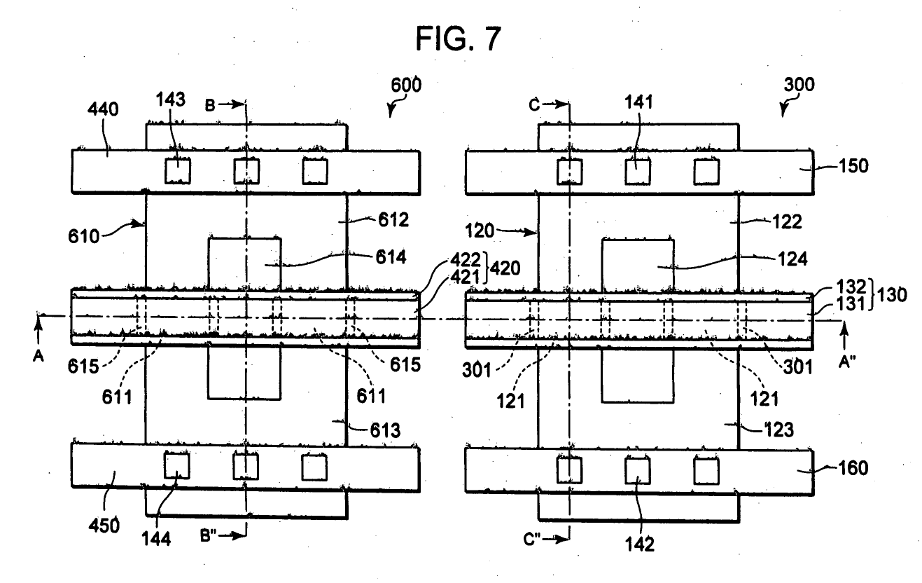

A semiconductor device according to a fourth embodiment of the present invention will next be explained using FIGS. 7 through 9.

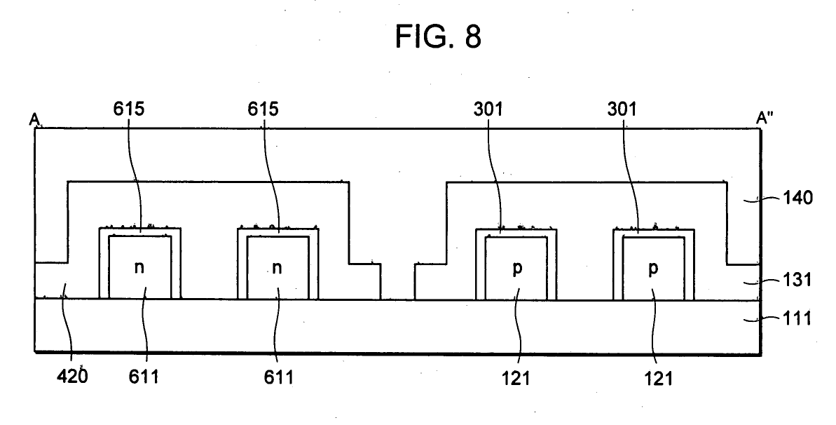

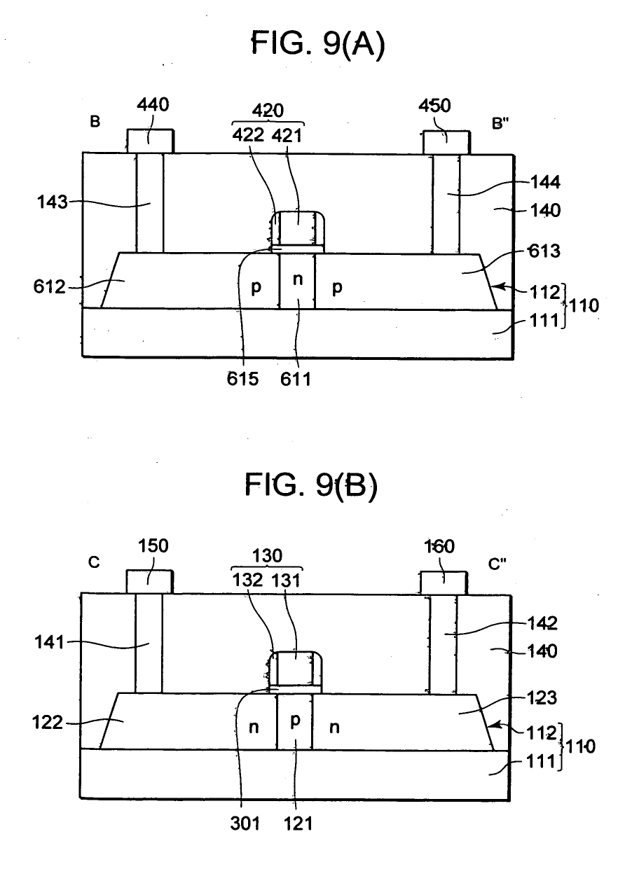

FIGS. 7 through 9 are respectively conceptual views showing a structure of the semiconductor device according to the present embodiment, wherein FIG. 7 is a plan view thereof, FIG. 8 is a sectional view taken along line A-A″ of FIG. 7, FIG. 9(A) is a sectional view taken along B-B″ of FIG. 7, and FIG. 9(B) is a sectional view taken along line C-C″ of FIG. 7, respectively. In FIGS. 7 through 9, the same reference numerals as those shown in FIGS. 1 through 6 respectively indicate the same constituent elements as those shown in these figures.

As shown in FIGS. 7 through 9, the semiconductor device according to the present embodiment is equipped with a p channel MOSFET 600 and an n channel MOSFET 300. The structure of the n channel MOSFET 300 is identical to the n channel MOSFET (refer to FIGS. 1 and 3) according to the second embodiment. On the other hand, the p channel MOSFET 600 has an element or device forming area 610.

The element forming area 610 is shaped in the form of a “□-shape, i.e., squared doughnut-shape” within a silicon epitaxial layer 112. The element forming area 610 has two channel forming sections 611, a source region 612 and a drain region 613.

The channel forming sections 611 are disposed at a “□-shaped, i.e., squared doughnut-shaped” portion placed directly below a gate pattern 420 with an element or device isolation region 614 interposed therebetween. The channel forming sections 611 are respectively shaped in the form of a hexahedral structure and are of n types. Gate oxide films 615 are respectively formed on both side surfaces and upper surfaces of the channel forming sections 611.

Thus, in the present embodiment, the gate oxide films 615 and 301 are formed on the side and upper surfaces of the channel forming sections 611 and 121 at both the n channel MOSFET 600 and the p channel MOSFT 300. Thus, in the MOSFETs 600 and 300, channels can be formed at both side and upper surfaces of the channel forming sections 611 and 121. Therefore, according to the present embodiment, both the p channel MOSFET 600 and the n channel MOSFET 300 are capable of increasing on-currents.

While the preferred forms of the present invention have been described, it is to be understood that modifications will be apparent to those skilled in the art without departing from the spirit of the invention. The scope of the invention is to be determined solely by the following claims.

What is claimed is:

1. A field effect transistor formed in a semiconductor substrate having a sapphire substrate and a silicon semiconductor layer, comprising:
channel forming sections each being a p type and having a hexahedral structure, which are formed using the silicon semiconductor layer;
an n type source region and an n type drain region formed using the silicon semiconductor layer so as to contact their corresponding end surfaces of the channel forming sections; and
a gate electrode formed so as to contact side surfaces of the channel forming sections through gate insulating films.

2. The field effect transistor according to claim 1, wherein the gate electrode is formed so as to contact only the side surfaces of the channel forming sections through the gate insulating films.

3. The field effect transistor according to claim 1, wherein the gate electrode is formed so as to contact both side surfaces and upper surfaces of the channel forming sections through the gate insulating films.

4. A semiconductor device formed in a semiconductor substrate having a sapphire substrate and a silicon semiconductor layer, comprising:
an n type field effect transistor including,
first channel forming sections each being a p type and having a hexahedral structure, which are formed using the silicon semiconductor layer,
an n type source region and an n type drain region formed using the silicon semiconductor layer so as to contact their corresponding end surfaces of the first channel forming sections, and
a first gate electrode brought into contact with side surfaces of the first channel forming sections through first gate insulating films; and
a p type field effect transistor including,
n type second channel forming sections each formed using the silicon semiconductor layer,
a p type source region and a p type drain region formed using the silicon semiconductor layer so as to contact their corresponding end surfaces of the second channel forming sections, and
a second gate electrode brought into contact with upper surfaces of the second channel forming sections through second gate insulating films.

5. The semiconductor device according to claim 4, wherein the first gate electrode is formed so as to contact only the side surfaces of the first channel forming sections through the first gate insulating films.

6. The semiconductor device according to claim 4, wherein the first gate electrode is formed so as to contact both side surfaces and upper surfaces of the first channel forming sections through the first gate insulating films.

7. The semiconductor device according to claim 6, wherein each of the second channel forming sections is shaped in the form of a hexahedral structure, and the second gate electrode is formed so as to contact both side surfaces and upper surfaces of the second channel forming sections through the second gate insulating films.
